(19) United States
(12) Patent Application Publication
(10) Pub. No.: US 2025/0183152 A1
(43) Pub. Date: Jun. 5, 2025

(54) HIGH VOLTAGE ISOLATION DEVICE

(71) Applicant: TEXAS INSTRUMENTS INCORPORATED, Dallas, TX (US)

(72) Inventors: Kozaburo Sakai, Allen, TX (US); Jeffrey Alan West, Dallas, TX (US); Jens Lohse, Allen, TX (US); Seungwon Yeom, Wylie, TX (US)

(21) Appl. No.: 18/524,402

(22) Filed: Nov. 30, 2023

(51) Int. Cl. H01L 23/522; H01L 21/768; H01L 23/00; H01L 23/532

(52) U.S. Cl. CPC H01L 23/5223; H01L 21/76819; H01L 21/76883; H01L 23/53295; H01L 24/05; H01L 2224/05567; H01L 2224/05573; H01L 2224/05624; H01L 2224/05644; H01L 2224/05647

(57) ABSTRACT

An integrated circuit (IC) including a capacitive HV isolation component and a method of fabrication thereof is disclosed. A SiN bilayer is disposed directly underneath a top electrode of the HV isolation component, where the SiN bilayer includes a top layer with a first RI formed over an underlying SiN layer having a second RI that is greater than the first RI.

### FIELD OF THE DISCLOSURE

Disclosed implementations relate generally to the field of integrated circuits (ICs) and IC fabrication. More particularly, but not exclusively, the disclosed implementations relate to an IC including a high voltage isolation device.

### BACKGROUND

Galvanic isolation is a principle of isolating functional sections of electrical systems or integrated circuits to prevent current flow while energy or information can still be exchanged between the sections by other means, such as capacitance, induction or electromagnetic waves, or by optical, acoustic or mechanical means. Galvanic isolation is typically used where two or more electric circuits communicate but their grounds or reference nodes may be at different potentials. It is an effective method of breaking ground loops by preventing unwanted current from flowing between two units sharing a reference conductor. Galvanic isolation is also used for safety, preventing accidental current flows from reaching ground though a person's body.

Isolators are devices designed to minimize direct current (DC) and unwanted transient currents between two systems or circuits, while allowing data and power transmission between the two. In most applications, isolators also act as a barrier against high voltage in addition to allowing the system to function properly. Where capacitive elements are used as isolators, dielectric breakdown is a key concern, especially in high voltage (HV) applications.

As the advances in the design of integrated circuits and semiconductor fabrication continue to take place, improvements in microelectronic devices, including galvanic isolators, are also being concomitantly pursued.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to an IC (also referred to as an electronic device, IC device, semiconductor device, etc.) including a capacitive HV isolation component where defectivity levels may be minimized while continuing to maintain the breakdown performance of the device. In various examples, a silicon nitride (SiN) bilayer is provided directly underneath a top electrode of the HV isolation component in order to ensure sufficient HV isolation, where the SiN bilayer includes a top SiN layer having suitable refractive index (RI) characteristics different from the RI characteristics of the underlying SiN layers, the differential RI characteristics of the top SiN layer facilitating a reduction in processing defects that may be caused by certain back-end-of-line (BEOL) stages of a fabrication flow.

In one example, an IC device is disclosed, which comprises, among others, a semiconductor substrate, a metal bottom plate over the semiconductor substrate, a metal top plate over the metal bottom plate, and a dielectric structure disposed between the top and bottom plates, the dielectric structure including a silicon nitride (SiN) bilayer underlying the top plate, where the SiN bilayer includes a first SiN layer directly contacting the top plate and having a first refractive index (RI), and a second SiN layer underneath the first SiN and having a second RI greater than the first RI. In some examples, the first SiN layer may have an RI of about 2.0 to 2.15 whereas the second SiN layer may have an RI of about 2.2 to 2.4. In some examples, the first SiN layer may have a thickness less than about 20% of a total thickness of the SiN bilayer.

In one example, a method of fabricating an IC device including an isolation component is disclosed. The method may comprise, among others, forming a bottom electrode of the isolation component over a semiconductor substrate, and forming a dielectric structure between the bottom electrode and a top electrode of the isolation component, where the dielectric structure includes a SiN bilayer underlying the top electrode, the SiN bilayer including a first SiN layer directly contacting the top electrode and having a first RI, and a second SiN layer underneath the first SiN and having a second RI greater than the first RI. In some examples, the method may further comprise forming an isolation break region in a portion of the SiN bilayer extending beyond the top electrode. In some examples, the SiN bilayer is formed over an oxynitride layer (e.g., a SiON layer) overlying a main dielectric component of the dielectric structure, the main dielectric component overlying the bottom electrode and having a thickness of at least 4 microns (μm). In some examples, the top electrode may be formed from a topmost metal layer of a multilevel metal interconnect formed over the semiconductor substrate. In some examples, the bottom electrode may be formed from an intermediate metal layer of the multilevel metal interconnect formed over the semiconductor substrate.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIGS. 1A and 1B respectively illustrate sectional and top plan views of an electronic device according to principles of the disclosure, including a capacitive HV isolation component implemented in a five-level-metal (5LM) process;

FIGS. 2A-2Q illustrate sectional views of the device of FIG. 1A at progressive stages of manufacturing; and

FIG. 3 is a flowchart according to an example IC fabrication method of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of a high voltage isolation device and a method of manufacturing the same will be set forth below in the context of capacitive isolation devices formed in the interconnect levels of an IC during back-end-of-line (BEOL) fabrication.

Circuit isolation, also known as galvanic isolation, may prevent direct current (DC) and unwanted alternating current (AC) signals from passing from one area of a system or a circuit to another area or circuit that needs to be protected, as previously noted. Among its uses, isolation may maintain signal integrity of the system or circuit by preventing high-frequency noise from propagating, protecting sensitive circuitry from high-voltage surges and spikes, and providing safety for human operators.

The high voltages present in factory automation, motor drives, grid infrastructure and electric vehicles (EVs), etc., can be several hundred or even thousands of volts. Galvanic isolation helps resolve the challenge of designing a safe human interface in the presence of such high voltages.

In some example implementations, galvanic isolators may be created by forming a parallel-plate capacitor using electrodes in different metallization layers of the integrated circuit, such as different metallization layers in the BEOL interconnect levels. The dielectric layers of the BEOL levels separate the electrodes to form the capacitor. For HV applications, the thickness of BEOL dielectric layers and/or the number of BEOL dielectric layers may be increased to provide a higher breakdown voltage. In some examples, a composite dielectric layer comprising silicon nitride (SiN) and silicon oxynitride (SiON) may be provided under the top electrode for improving HV isolation performance.

Chemical-mechanical polishing/planarization (CMP), including electrochemical-mechanical polishing (eCMP), may be used to smooth, or planarize a material layer prior to forming vias through the material layer. In some examples the planarized layer includes composite SiON/SiN layers formed in the fabrication of HV isolation devices. The CMP process uses an abrasive and corrosive slurry together with a polishing pad and retaining ring, typically of a greater diameter than the wafer. The pad and wafer are pressed together by a dynamic polishing head and held in place by a retaining ring. The dynamic polishing head is rotated with different axes of rotation which removes material from the surface of the wafer and tends to even out any irregular topography, making the wafer surface planar.

CMP, a tribochemical and electrochemical process based on the synergy between various mechanical and electrochemical mechanisms, uses a variety of slurry materials and electrolytes for polishing and planarization. The slurry often contains particles composed of alumina, silica, and/or cerium oxide (ceria), etc., suspended in an acidic or basic solution. During the manufacturing process the suspended particles can settle and form what are known as large particle counts, which can be difficult to remove in a post-CMP cleaning process due to the complex interaction of the different materials involved that are often extant in multiple phases, e.g., gas, liquid, and/or solid phases. Because of the difficulty in the removal of particulate matter generated and/or introduced in CMP, any entrapped particulate matter may increase the risk of defectivity in the device, which can compromise the device's HV breakdown performance.

Examples of the present disclosure recognize the foregoing challenges and accordingly provide a technical solution for fabricating IC devices, including those implementing a capacitive HV isolation component, where CMP-associated defectivity may be advantageously reduced prior to or during via formation without significantly reducing the HV breakdown/isolation performance of the device. Depending on application, examples herein include forming a SiN bilayer directly underneath a top electrode of a capacitive HV component, where an upper portion of the SiN bilayer comprises nitride material having predetermined refractive index (RI) characteristics configured to enhance protection against defect formation as will be set forth in detail further below. While such examples and variations may be expected to reduce manufacturing defects that could otherwise reduce yields, reliability or electrical performance, no particular result is a requirement of the present disclosure unless explicitly recited in a particular claim.

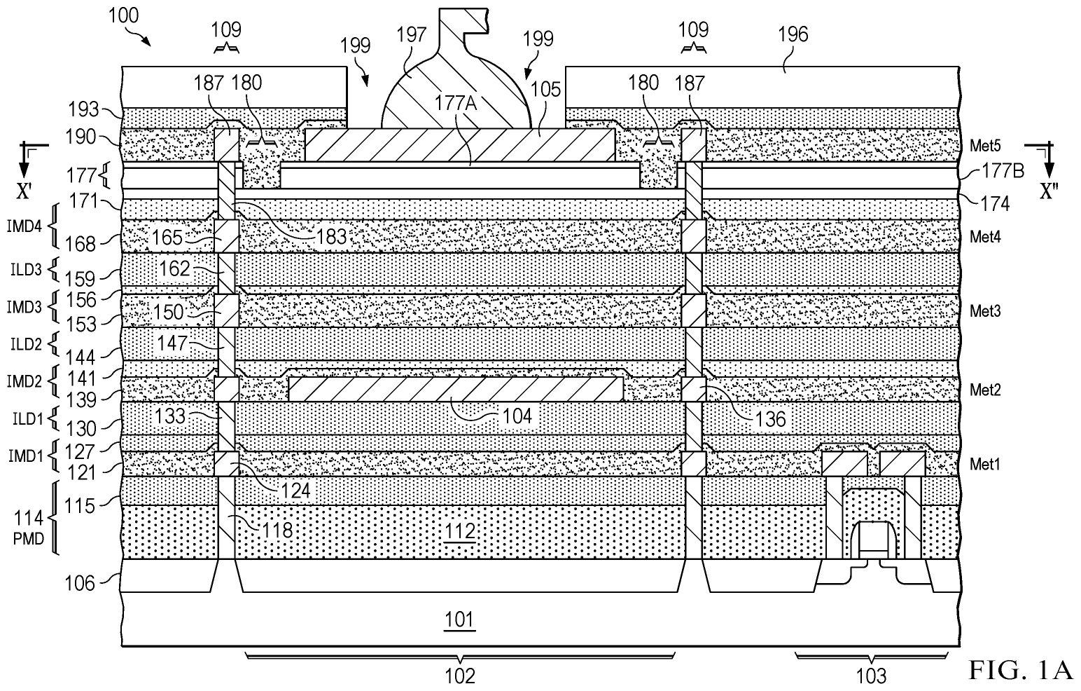

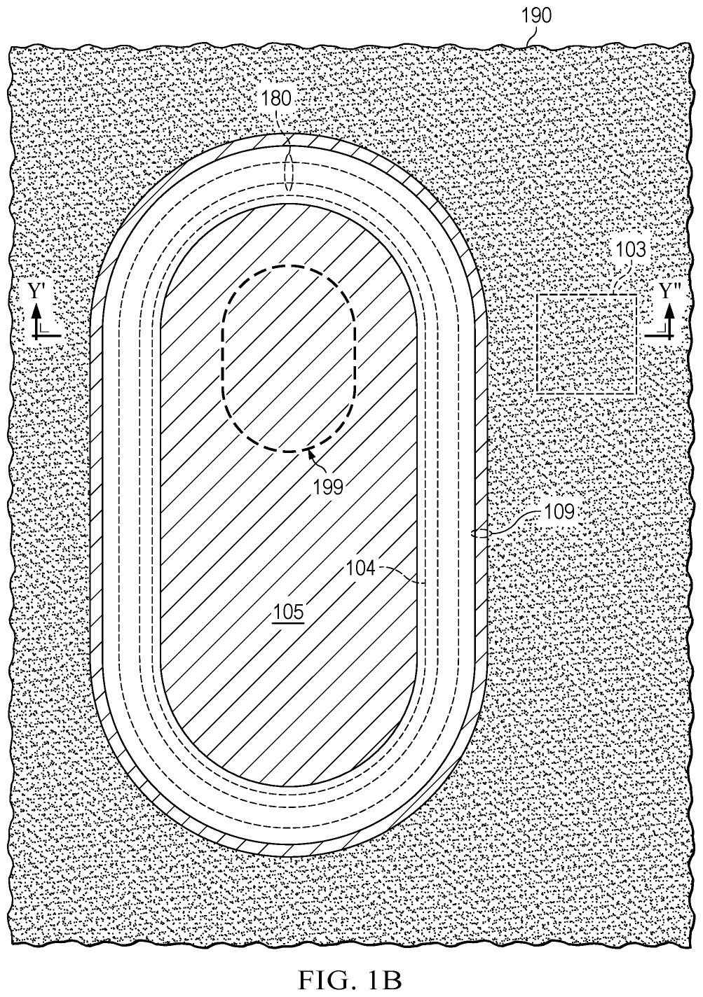

Turning to FIG. 1A, an electronic device 100, e.g., an IC device, is shown in a sectional view where a capacitive HV isolation component may be provided according to some examples herein. Corresponding FIG. 1B shows the device 100 in a top plan view taken along a horizontal plane, e.g., X′-X″ plane, disposed at a top metallization level, e.g., MET5, shown in FIG. 1A. The electronic device 100 includes a semiconductor substrate 101 over which a capacitor 102 operable as a galvanic HV isolation device and an optional transistor 103 are formed. Depending on application, the semiconductor substrate 101 may predominantly comprise suitably doped silicon in some examples, although other semiconductor materials such as, Ge, SiGe, GaAs, SiC, GaN, other Group III-V materials, etc., may be used in some implementations, where one or more epitaxial layers or single-crystal layers may be formed or provided in certain areas of the semiconductor substrate 101 in some arrangements.

The capacitor 102 includes a first electrode 104 and a second electrode 105. Without limitation, implied or otherwise, the first electrode 104 may be referred to as bottom plate/electrode or lower plate/electrode 104, and the second electrode 105 may be referred to as top plate/electrode or upper plate/electrode 105. In various examples the top plate 105 and the bottom plate 104 are about the same size and shape, although it is not a necessary requirement for purposes of the present disclosure. Further, in an example implementation, the bottom plate 104 may be disposed directly between the top plate 105 and the substrate 101 along a surface normal, e.g., with or without varying amounts of overlap between the two plates. The top plate 105 may be connected to a high-voltage circuit node, while the bottom plate 104 and the transistor 103 may be connected to a low-voltage circuit node in some arrangements.

In some examples, the bottom plate 104 and/or the top plate 105 may have a minimum length along a longest axis of about 30 μm. Likewise, the bottom plate 104 and/or the top plate 105 may each have a minimum length along an orthogonal shortest axis of about 30 μm. In some examples, each of the bottom plate 104 and the top plate 105 may have an aspect ratio (e.g., length of longest axis divided by length of orthogonal shortest axis) of in a range between about one and about five. The plates 104 and 105 are not limited to any particular shape, which may comprise a variety of geometrical shapes, e.g., squares, circles, ovals, ellipses, rectangles, ovoids, coils/serpentines, racetracks, obrounds, trapezoids, rhomboids, regular or irregular polygons, etc. In some further examples, the plates 104 and 105 may have a minimum lateral width (parallel to the substrate 101 surface) sufficient to facilitate the formation of a wire bond, e.g., bond 197, with respect to the top plate 105, in order to provide connectivity with external circuitry (not shown in this Figure). Such minimum width may depend on the wire bonding technology, and without any limitation, may be about 80 μm. In one non-limiting example, the plates 104 and 105 each have a short axis length of about 120 μm and a long axis length of about 160 μm. In another non-limiting example, the plates 104 and 105 are both of a circular shape, with a diameter of about 100 μm. In some examples, one of the bottom plate 104 and the top plate 105 may be implemented as a plurality of plates, e.g., two plates. Thus, in one non-limiting example, the bottom plate 104 may be a single continuous metal plate, while the top plate 105 may be two noncontiguous metal plates. In such examples, the two or more plates need not be a same shape, or have a same area.

The example of FIG. 1A illustrates a five-level-metal (5LM) device 100, without any limitation thereto. The device 100 therefore includes five metal levels designated MET1-MET5. Each metal level includes metal features within a corresponding inter-metal dielectric (IMD) layer IMD1-IMD5. An interlevel dielectric (ILD) layer is located between each IMD layer, such that there are four dielectric layers ILD1-ILD4 in the illustrative example of FIG. 1A. A pre-metal dielectric (PMD) layer 114, which may comprise one or more (sub) layers, is located between the IMD1 level and the substrate 101. A passivation/protective overcoat (PO) layer comprising one or more (sub) layers overlies the top metal layer MET5. In some arrangements, the PMD layer 114 may be comprised of materials operable as a penetration barrier to various impurities created by one or more CMP or other processes that may be employed in the fabrication of the various MET layers and interconnecting vias operable to provide electrical connectivity between two or more MET layers disposed at different levels. Depending on implementation, example PMD materials may comprise, low-pressure tetra-ethyl-ortho-silicate glass (LP-TEOS), Si-rich (SR)-oxide, plasma-enhanced (PE)-oxynitride, PE-nitride, PE-TEOS films, etc., and may be doped with fluorine or phosphorous.

An optional isolation structure 106, e.g., a shallow trench isolation (STI) structure, may be disposed between the PMD layer 114, e.g., comprising (sub) layers 112, 115, and the substrate 101. In some examples, the isolation structure 106 may be configured to reduce capacitive coupling between the bottom plate 104 and the substrate 101. In other examples, not shown, the isolation structure 106, if present, may include one or more doped well regions that may provide junction isolation between the bottom plate 104 and the substrate 101. As depicted in FIG. 1A, the bottom plate 104 may be formed from a metallic structure disposed in the MET2 level of the illustrated 5LM metal interconnect example, but could be located in another metal level in other examples. The level in which the bottom plate 104 is located may be selected in part based on design considerations such as the desired isolation of the bottom plate 104 from the substrate 101, expected capacitive coupling to the top plate 105, etc.

The plates 104 and 105 may be comprised of any suitable metal. Examples described herein may describe the plates 104 and 105 as being formed from aluminum (Al), although other metal interconnect systems, such as copper (Cu) or gold (Au), may be used in additional and/or alternative arrangements without undue experimentation. The top plate 105 may be configured to receive a high voltage signal, e.g., via a wire ball-bonded to the top plate 105. The high voltage signal may be received from a high-voltage source to which the device 100 is connected, e.g., another IC operating in a high voltage domain, an electric motor, etc., to provide data transmission or an electronic function such as monitoring or controlling. Depending on implementation, “high voltage” may refer to a static or RMS voltage of about 100 V or more, and “low voltage” may refer to a static or RMS voltage of about 20 V or less for purposes of some examples herein, without limitation.

The top plate 105 is capacitively coupled to the bottom plate 104 through the one or more intervening dielectric layers, e.g., ILD1-ILD4 and corresponding IMD1-IMD4 in the illustrated arrangement of FIG. 1A. The coupling may induce on the bottom plate 104 an attenuated electric signal corresponding to the high-voltage signal present at the top plate 105. The attenuated signal at the bottom plate 104 may be coupled to another electronic device on another semiconductor substrate, or may be routed to an electronic device located on the same substrate, such as the transistor 103. In some examples, the plates 104 and 105 may be located between via stacks, described further below, that connect to the substrate 101. The substrate 101 may provide a ground reference for the via stacks, e.g., such that the via stacks may provide a guard ring 109 operable as part of a Faraday cage capable of terminating or otherwise containing electric field lines associated with the plates 104 and/or 105.

For purposes of some examples of the present disclosure, three types of silicon dioxide dielectric materials are described. Two types may be produced by a plasma-enhanced chemical vapor deposition (PECVD) process in a capacitively-coupled plasma reactor using tetraethoxysilane (TEOS) feedstock. These dielectrics are referred to herein as “PE-TEOS”, where a first type of PE-TEOS is a “high-stress” PE-TEOS and a second type of PE-TEOS is “low-stress” PE-TEOS, without limitation. In a non-limiting example, a “high-stress” PE-TEOS process may be configured to produce an SiO₂ layer with about 120 MPa (megapascal) compressive stress, whereas a “low-stress” PE-TEOS process may be configured to produce an SiO₂ layer with about 20 MPa compressive stress. A third type of silicon dioxide may be produced using by a high-density plasma in an inductively-coupled reactor, and is referred to as “HDP oxide”, without limitation. In some arrangements, HDP oxide and/or high-stress PE-TEOS may be used as the dielectric in close proximity to or in contact with the plates 104 and 105, while one or more of the dielectric levels between the plates 104 and 105 include low-stress PE-TEOS to reduce the impact/extent of wafer bow. Additional details with respect to forming PE-TEOS and HDP oxide layers that may be implemented in some examples of the present disclosure may be found in U.S. Pat. No. 11,495,658, which is incorporated by reference herein for all purposes.

Continuing to refer to the example of FIG. 1A, the PMD layer 114 is illustrated as a composite layer comprising layers 112, 115, where a phosphorous-doped silicate glass (PSG) material is used for forming layer 112 and a high-stress PE-TEOS material is used for forming layer 115, each having a suitable thickness depending on implementation. In some other examples the PMD layer 114 may be undoped and formed from a single dielectric type. The specific selection of the PMD layer materials may depend on, e.g., the type and functionality of transistors included in the device 100. In some arrangements, the IMD1 layer may include an HDP oxide sublayer 121 and a high-stress PE-TEOS sublayer 127. Such a configuration may be produced by first depositing the HDP oxide sublayer 121 over MET1 features, with the MET1 features producing a topography in the HDP oxide sublayer 121. As used herein, the term “topography” may be defined as a deviation of the top surface of a material layer from planarity by at least 10% of the layer thickness within a lateral distance of three times the layer thickness. The high-stress PE-TEOS sublayer 127 of IMD1 is formed over the HDP oxide sublayer 121 and planarized to produce a suitable surface for subsequent processing as will be set forth further below. A high-stress PE-TEOS layer 130 is then formed as part of ILD1 over the planarized surface of the high-stress PE-TEOS sublayer 127.

In the illustrated example, the bottom plate 104 is formed in the MET2 level that is formed over the high-stress PE-TEOS sublayer 130, where an HDP oxide layer 139 is formed as part of the IMD2 layer over the bottom plate 104. Accordingly, the bottom plate 104 is bounded by HDP oxide on top and side surfaces, and by high-stress PE-TEOS on the bottom surface. The bottom plate 104 and the top plate 105 are spaced apart by a dielectric stack structure comprising portions of or formed from the various ILD and IMD layers, which may comprise PE-TEOS and/or HDP oxide materials, where a silicon nitride (SiN) bilayer forming part of the dielectric stack structure may be formed directly underlying the top plate 105 for purposes of the present disclosure as will be set forth further below.

In the illustrated example, portions of the ILD2, IMD3, ILD3, IMD4 and ILD4 layers may be operable as part of a vertical stack structure of dielectrics (not specifically labeled with a reference number in FIG. 1A) disposed between the bottom and top plates 104, 105, respectively. In some arrangements, the IMD2, IMD3 and IMD4 layers or levels may each include a respective PE-TEOS layer 141, 156, 171.

The top plate 105 may be located at least partially within the IMD5 layer, which includes an HDP oxide layer 190, where the HDP oxide layer 190 covers or touches sidewalls and a portion of the top surface of the top plate 105 such that only an opening 199 formed for wire bonding is exposed. In similar fashion, a TEOS layer 193 having an opening corresponding to the wire bond opening of the HDP oxide layer 190 may be formed thereover. A suitable PO layer 196 may be formed to cover remaining portions of the TEOS layer 193 of the IMD5 level. Additionally, the PE-TEOS layer 171 of IMD4 is covered by a SiN bilayer 177 and an SiON layer 174 for enhancing HV breakdown performance of the electronic device 100 in some examples.

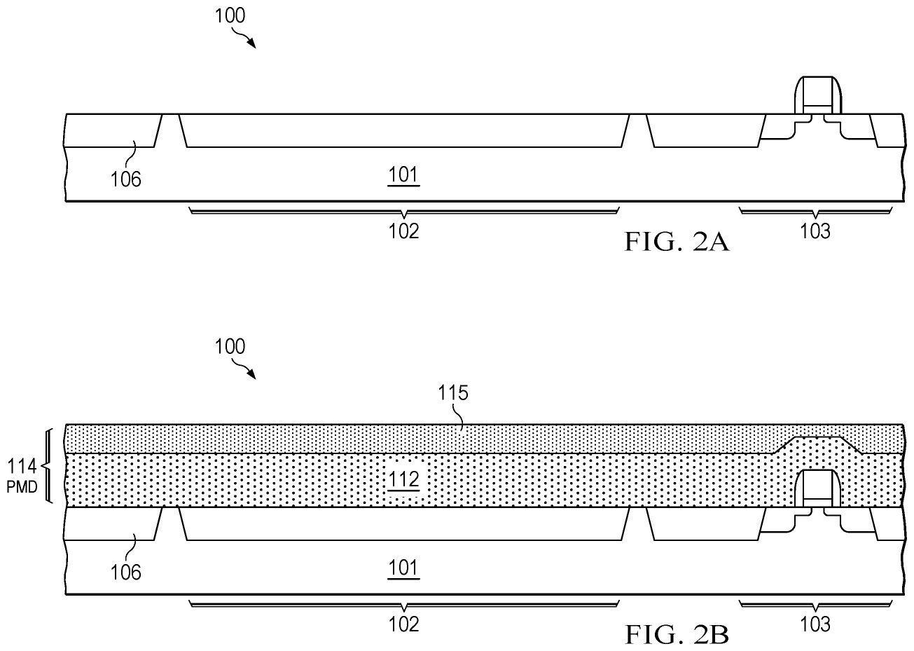

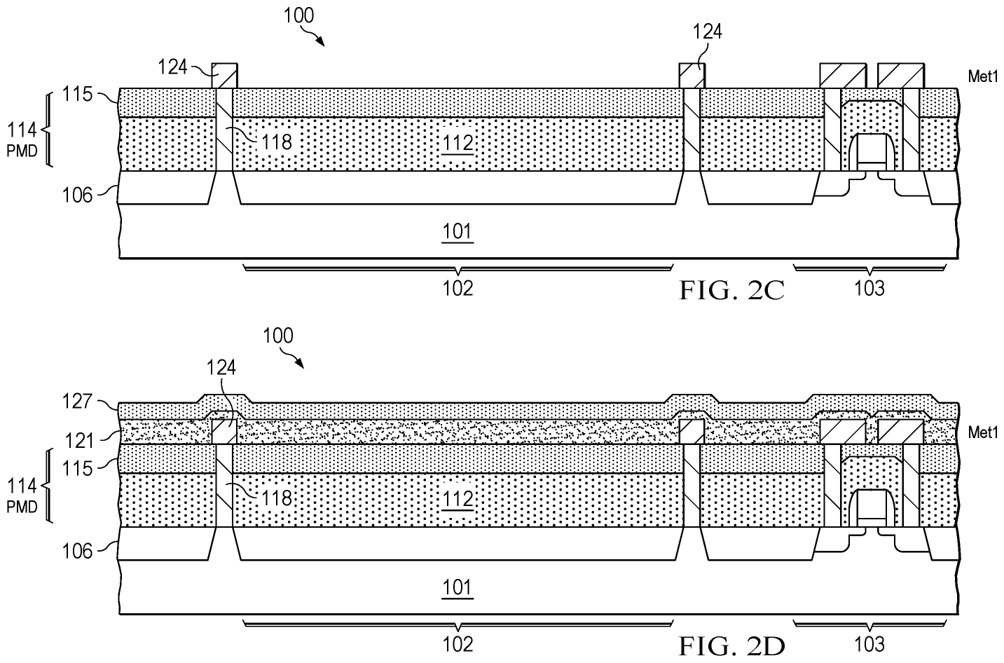

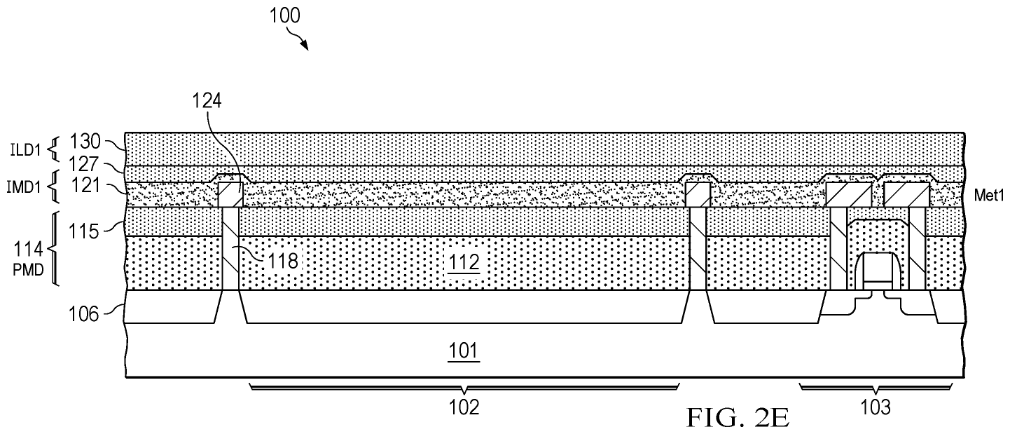

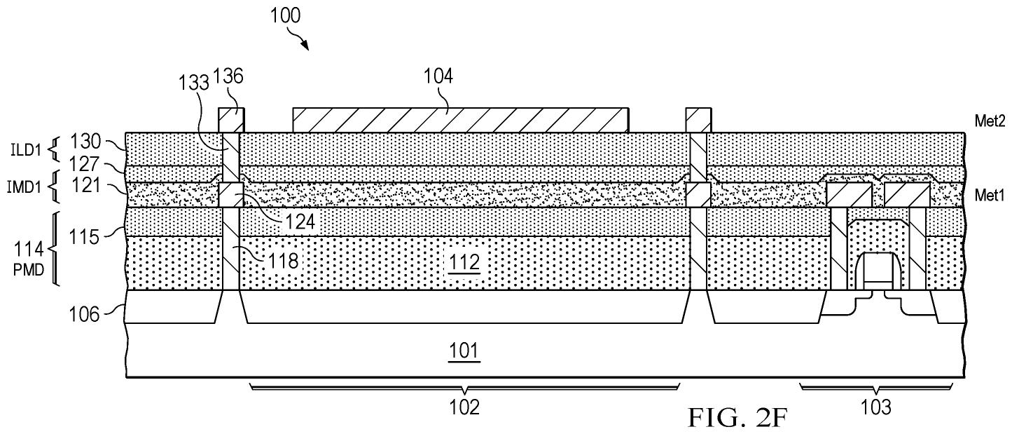

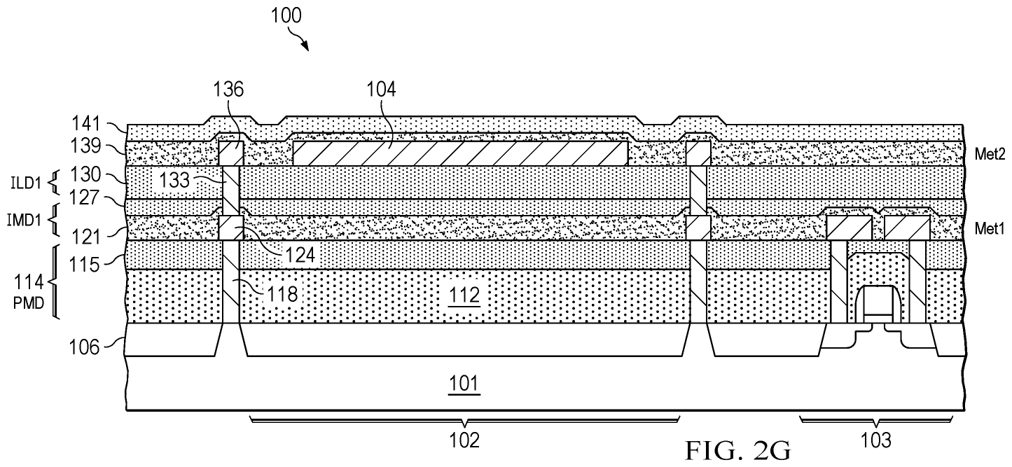

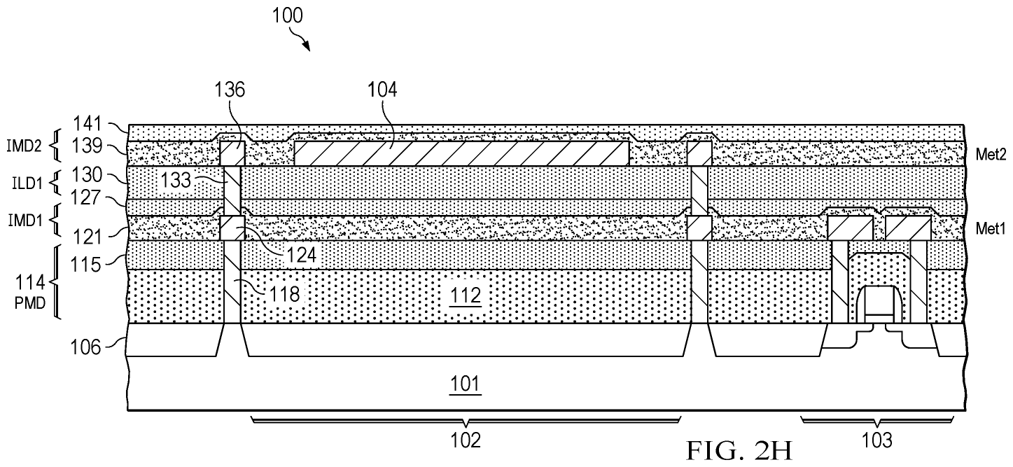

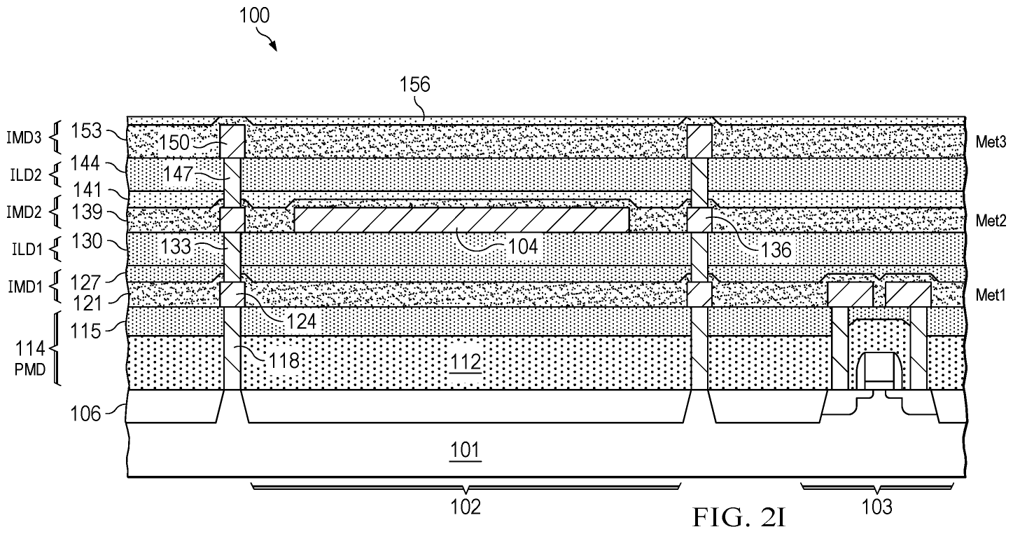

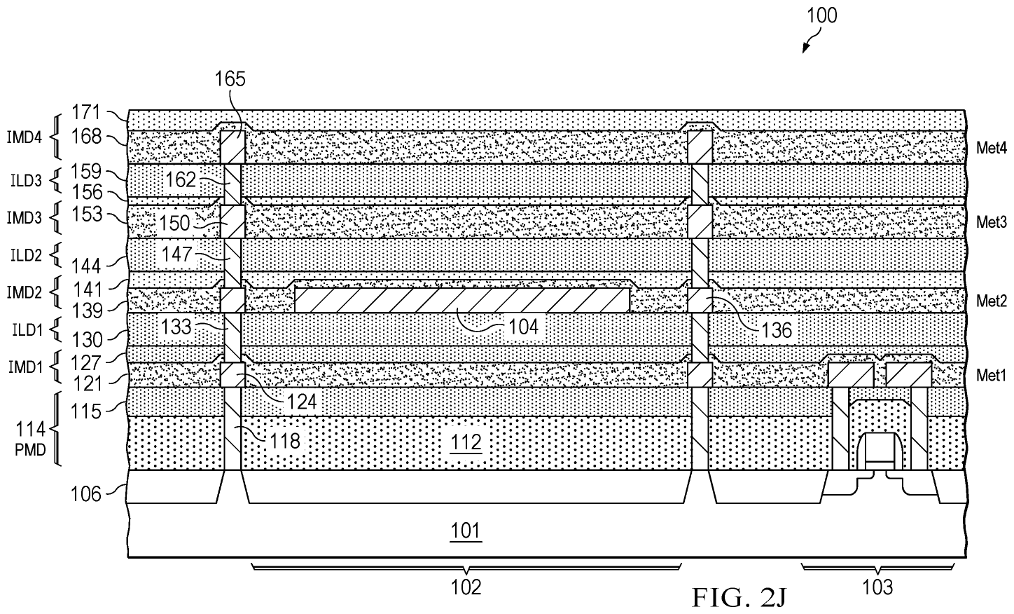

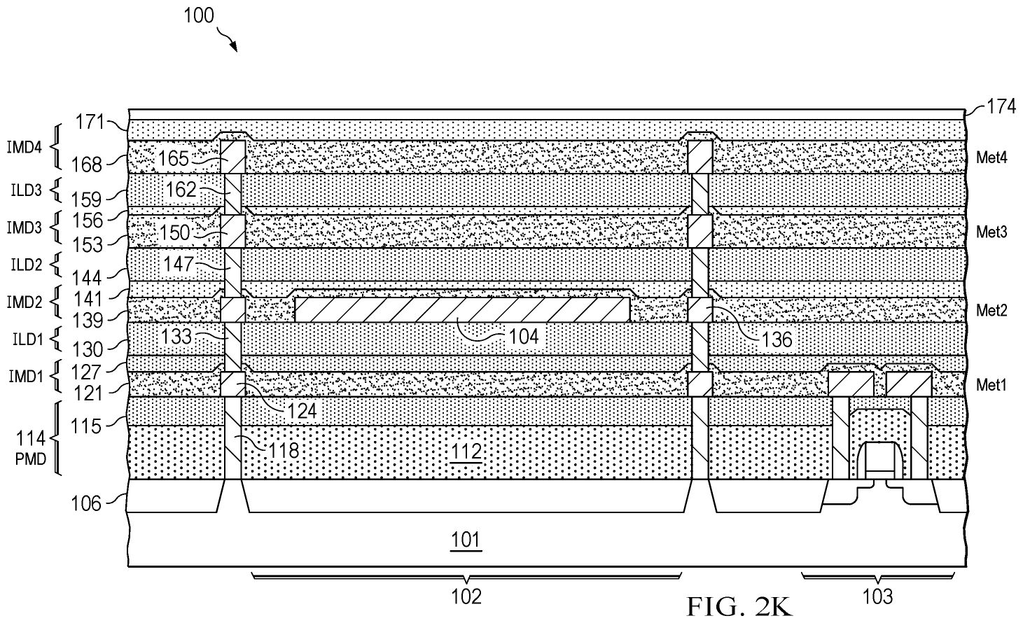

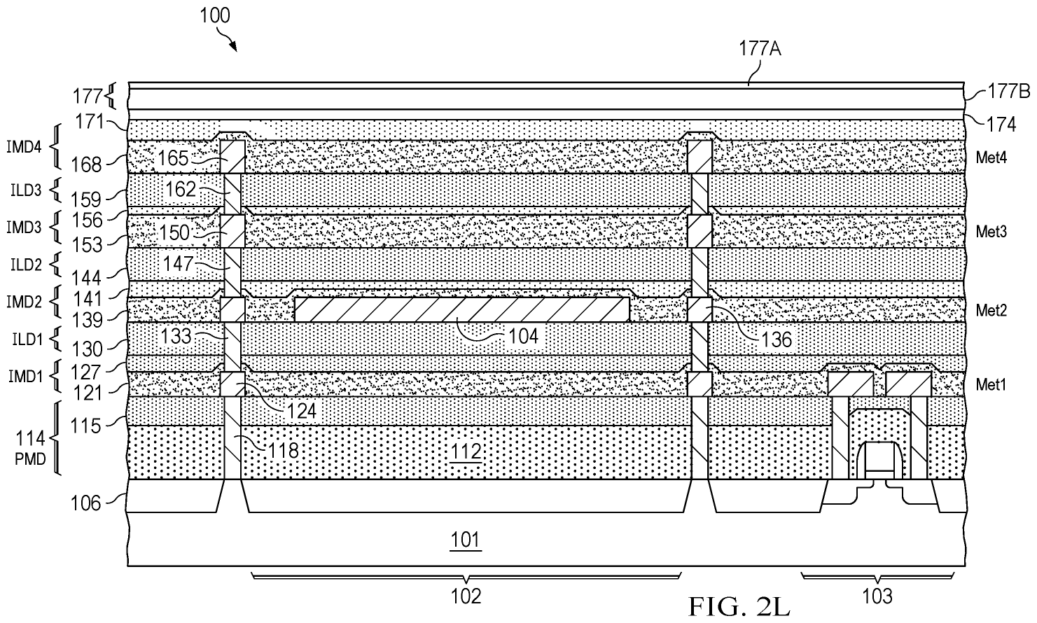

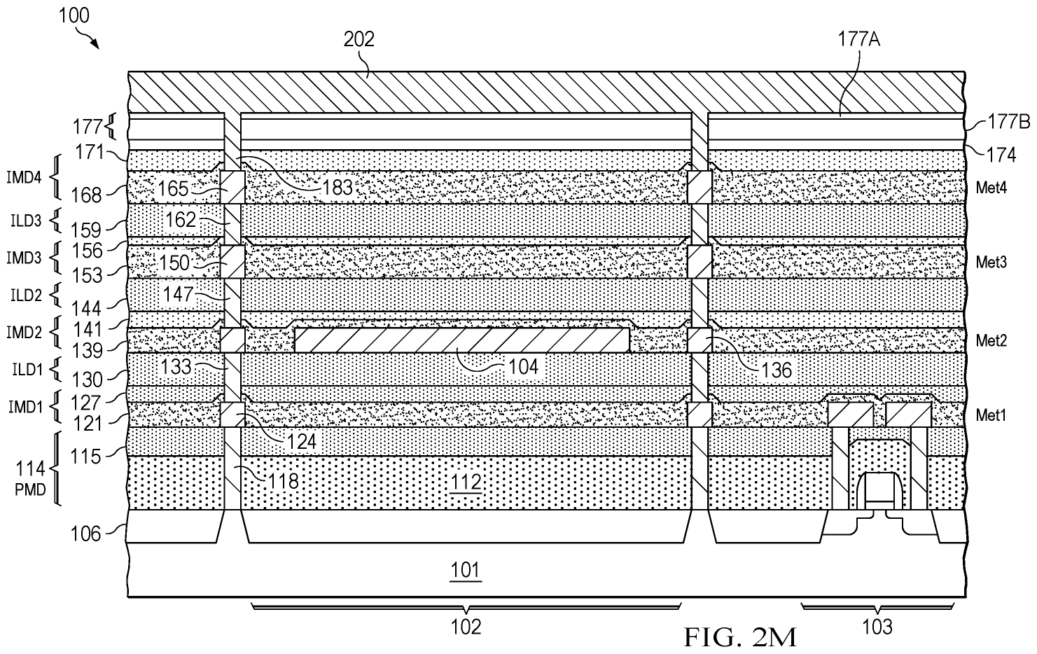

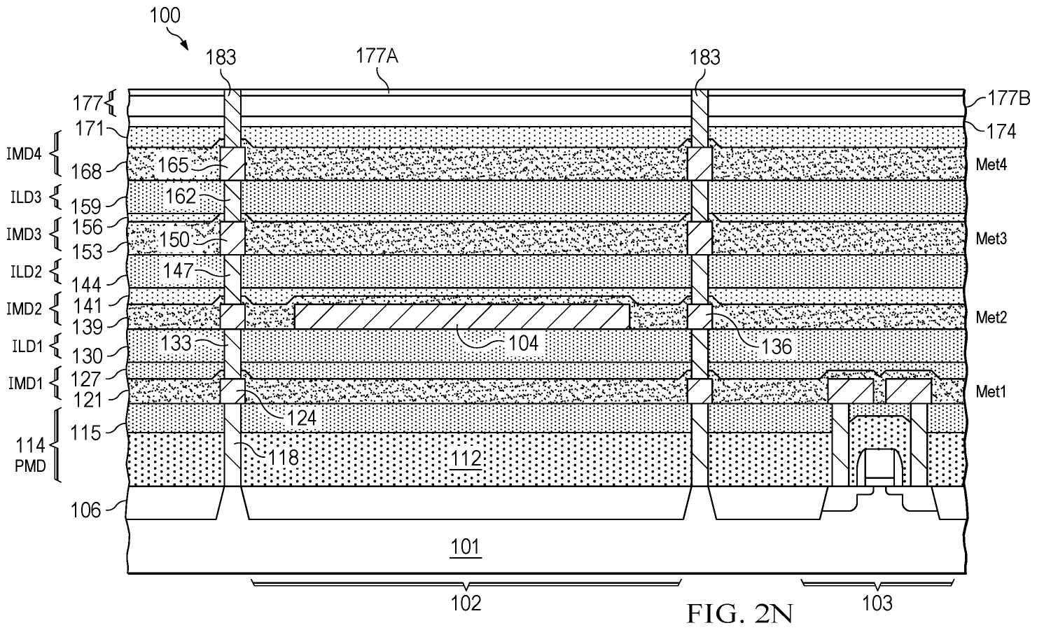

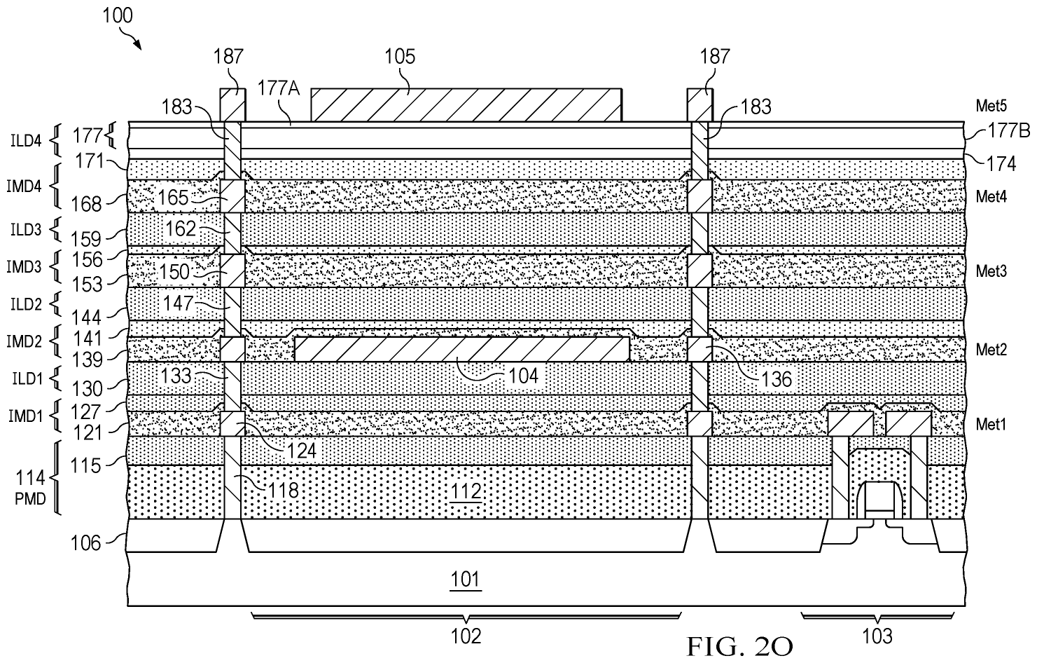

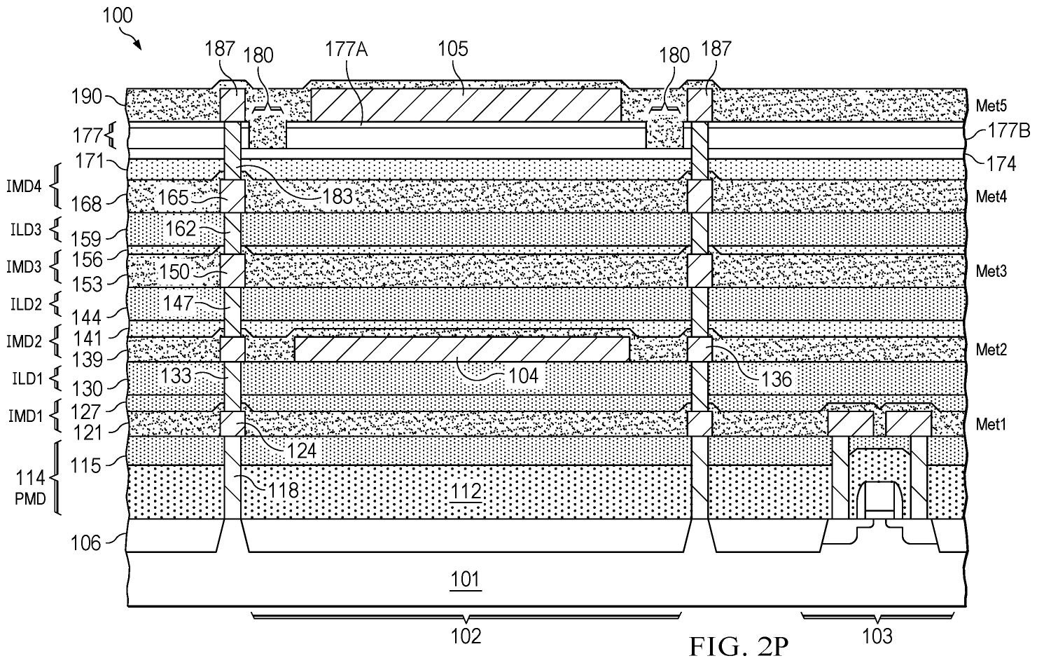

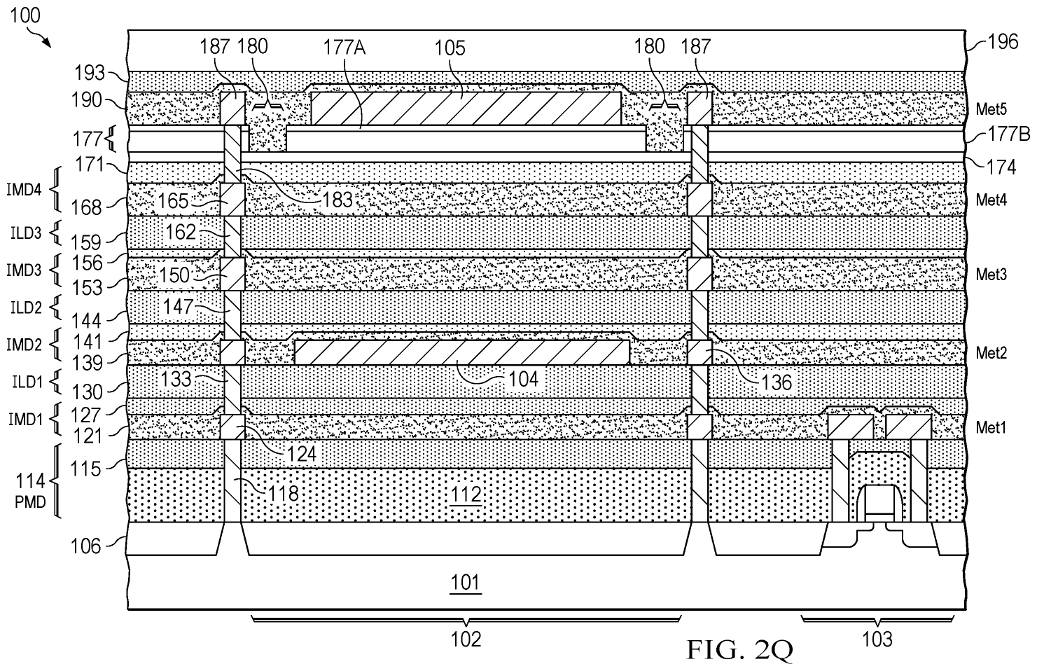

In various examples of the present disclosure, the SiN bilayer layer 177 may be formed as a composite bilayer having a first SiN layer 177A (also referred to as top or upper SiN layer) with a low refractive index (RI) range that is in contact with and directly underlying the top plate 105. The upper SiN layer 177A having a low RI relative to an underlying second SiN layer 177B (also referred to as a bottom or lower SiN layer) may be provided for reducing potential defectivity that may be caused due to upper level via processing by CMP, as will be described below in reference to the cross-sectional views of FIGS. 2A-2Q. In order to maintain the desired HV breakdown performance, which requires a SiN layer having higher RI values in some examples, the second SiN layer 177B having suitable RI and thickness relative to the first SiN layer 177A may be provided over the SiON layer 174 and underlying the first SiN layer 177A according to the teachings herein. Accordingly, the first SiN layer 177A (or sublayer) may have a first RI and the second SiN layer 177B (or sublayer) may have a second RI, where the first RI is less than the second RI, e.g., by a certain value depending on implementation. In some arrangements, the first SiN layer 177A may have an RI in the range of about 2.0 to 2.15 and the second SiN layer 177B may have an RI in the range of about 2.2 to 2.4, without limitation.

In some arrangements, the PE-TEOS layers 141, 156, 171 may be provided as low-stress layers that may be encapsulated by other dielectric layers that effectively prevent moisture diffusion into the dielectric stack and/or prevent significant out-diffusion of moisture incorporated in the PE-TEOS layers during manufacturing. In other examples, not shown, configured to operate in relatively low-voltage applications in which the risk of dielectric breakdown near corners of the top plate 105 is reduced, low-stress PE-TEOS layers may be replaced by high-stress PE-TEOS layer of similar thicknesses, respectively.

In the example of FIG. 1A, an oxide layer may be disposed in direct contact with one or more neighboring oxide layers. In other examples, a thin layer of a dissimilar dielectric may be placed between some neighboring oxide layers. By way of illustration, a nitrogen-containing dielectric such as SiN or SiON may be placed between a low-stress PE-TEOS layer and a high-stress PE-TEOS layer, or between a low-stress PE-TEOS layer and an HDP oxide layer. The dissimilar dielectric, if used, may be a thin layer, e.g., 30 nanometers (nm) to 300 nm, to minimize the contribution to the cumulative stress of the dielectric stack in some additional, alternative and/or optional arrangements. With respect to the particular 5LM device 100 shown in FIG. 1A, IMD1 is illustrated as layers 121, 127; ILD1 is illustrated as layer 130; IMD2 is illustrated as layers 139, 141; ILD2 is illustrated as layer 144; IMD3 is illustrated as layers 153, 156; ILD3 is illustrated as layer 159; IMD4 is illustrated as layers 168, 171; ILD4 is illustrated as SiN bilayer 177 and SiON layer 174; and IMD5 is illustrated as layers 190, 193. In some examples, optional isolation breaks or cutouts 180 in the SiON/SiN composite layer 174/177 may be provided in order to enhance lateral breakdown performance of the device 100, especially in applications involving 1000V or higher, as set forth in U.S. Pat. No. 9,299,697, which is incorporated by reference herein for all purposes. Further, reference numbers 124, 136, 150, 165, and 187 refer to various metal structures at MET1-MET5 levels, respectively. Additionally, contact vias 118 through PMD 114 as well as inter-level vias 133, 147, 162, and 183 through corresponding ILD1-ILD4 layers are illustrated in the example of FIG. 1A.

FIG. 1B illustrates a top plan view of the device 100 along the plane X′-X″ in MET5 level shown in FIG. 1A as previously noted. As shown in FIG. 1B, the HV isolation capacitor 102 may be provided as having a racetrack or an obround shape, where an opening of suitable size and shape, e.g., opening 199, overlying the top plate 105 and through a topmost IMD sublayer, e.g., layer 190 of IMD5, is illustrated. A vertical cross-section along a normal plane Y′-Y″ orthogonal to a horizontal plane of the device 100, e.g., the layer 190, yields a sectional view such as the view described above in detail in reference to FIG. 1A.

FIGS. 2A-2Q illustrate sectional views of the device of FIG. 1A at successive stages of manufacturing according to some examples. In FIG. 2A, the substrate 101 is shown with the transistor 103 having been formed, where the location of the capacitor 102 is shown for reference. As described previously, one or more isolation structures 106 may be formed in the substrate 101 relative to the capacitor 102 and other circuit components, e.g., transistor 103. Further, where some examples do not include the transistor 103 or other circuitry, such examples are illustrative of an arrangement where the capacitor 102 may be referred to as a “standalone” capacitor. As noted previously, the substrate 101 may be any suitable substrate, e.g., semiconducting or insulating. In some examples, the substrate 101 is a silicon wafer or a portion of a silicon wafer (e.g., a semiconductor die), and may be doped with suitable dopants, e.g., p-type dopants.

FIG. 2B is representative of a stage where the PMD layer 114 has been formed. In the illustrated example, shown without limitation, a dielectric layer 112 is formed over the substrate 101, which projects a vertical and/or conformal topography above the transistor 103. The dielectric layer 112 may be a PSG layer, as noted previously. As shown in FIG. 2B, a dielectric layer 115 of high-stress PE-TEOS may be formed over the dielectric layer 112 and planarized to reduce the topography. In other examples, such as when the device 100 is a standalone device, an undoped dielectric may be used for the dielectric layer 112, e.g., high-stress PE-TEOS, and planarization may be omitted. In such examples, a SiN layer with a compressive stress of about 100 MPa may be used for the layer 115.

In FIG. 2C, contacts 118, e.g., tungsten plugs, formed through the dielectric layers 112 and 115 are operable to contact the substrate 101 in the region of the capacitor 102. Additional unreferenced contacts may be provided for effectuating connectivity with respect to other components of the device 100, e.g., source/drain regions of the transistor 103. A metal layer may be formed over the dielectric layer 115 and patterned to form metal structures 124 connected to the contacts 118, and unreferenced interconnects connected to the source/drain contacts of the transistor 103. Example metal structures 124 may operate as a landing pad for a subsequent via in the corresponding via stack (as illustrated in FIG. 1A) or may form a closed loop with a corresponding other of the metal structures 124. The metal layer from which the metal structures 124 are formed may be an Al layer, without limitation, and the patterning may include baseline lithography and metal etch processes.

FIG. 2D illustrates the partially formed device 100 after deposition of a first IMD layer. An HDP oxide layer 121 of appropriate thickness may be formed initially. In some examples, HDP oxide may be preferred when spacing between the metal structures 124, or other metal features outside the view of the Figure, is small enough that PE-TEOS may not effectively fill the space. In other examples with more relaxed spacing, PE-TEOS may be used instead. In the illustrated example, a dielectric layer 127 of high-stress PE-TEOS is formed over the HDP oxide layer 121. Topography associated with the metal structures 124 may extend to the surface of the PE-TEOS layer 127, which may be planarized using suitable process, e.g., CMP, in order to remove a portion of the PE-TEOS layer 127, thus reducing the surface topography. FIG. 2E shows the device 100 after planarization of the PE-TEOS layer 127 and deposition of a PE-TEOS layer 130 on the planarized surface. The HDP oxide layer 121 and PE-TEOS layer 127 are designated IMD1, and the PE-TEOS layer 130 is designated ILD1 as previously noted. In another example, not shown, the PE-TEOS layer 127 may be deposited with a sufficient thickness to act as both the upper portion of the IMD1 level and as the ILD1 level, with the surface of the single PE-TEOS layer then planarized. This alternative implementation may be appropriate when the metal structures 124 have a maximum thickness of about 500 nm, for example.

FIG. 2F illustrates the device 100 after forming a MET2 layer over the PE-TEOS layer 130 and patterning the MET2 layer to produce the bottom plate 104 and MET2 structures 136. Vias 133 are formed within ILD1, e.g., using tungsten (W) metallurgy, connecting the MET2 structures 136 to the MET1 structures 124. Similar to the MET1 level, the MET2 layer may be formed from Al. Depending on implementation, the MET2 structures 136 may follow a layout similar to that of the MET1 structures 124.

FIG. 2G illustrates the stage where an HDP oxide layer 139 and a PE-TEOS layer 141 have been formed over the bottom plate 104. The topography of the PE-TEOS layer 141 surface conforms to the underlying MET2 structures 136 and bottom plate 104. Thus, a CMP process may also be used at this stage to reduce the surface topography. FIG. 2H illustrates the device 100 after planarization of the PE-TEOS layer 141. The HDP oxide layer 139 and remaining PE-TEOS layer 141 may be designated IMD2 as previously noted.

FIG. 2I illustrates the device 100 after forming the PE-TEOS layer 144, HDP oxide layer 153 and PE-TEOS layer 156 over the planarized surface, where MET3 structures 150 and associated vias 147 to lower level MET2 structures 136 may be formed using suitable metallization processes and metallurgies, e.g., AL, Cu, W, etc. The PE-TEOS layer 144 is designated ILD2, and the HDP oxide layer 153 and PE-TEOS layer 156 are designated IMD3. Similar to the formation of lower levels, the surface of the PE-TEOS layer 156 may be planarized. The sequence of manufacturing steps used to produce the ILD2 and IMD3 as well as the vias 147 and MET3 structures 150 may be repeated as needed to provide a desired distance between the bottom plate 104 and the top plate 105. Suitable adjustments may be made to accommodate metal spacing and thickness as well as any requirements imposed by baseline and/or qualified processes in a particular manufacturing facility.

In the illustrated example, another via and metal level is formed, as shown in FIG. 2J. In this example, a PE-TEOS layer 159 is formed over planarized PE-TEOS layer 156, followed by an HDP oxide layer 168 and another PE-TEOS layer 171. MET4 structures 165 are located within the HDP oxide layer 168, where vias 162 through the layer 159 are formed to connect the MET4 structures to the MET3 structures. As previously noted, the PE-TEOS layer 159 is designated ILD3 and the HDP oxide layer 168 and low-stress dielectric layer 171 are designated IMD4.

In FIG. 2K, a SiON layer 174 is formed over the PE-TEOS layer 171 as part of a composite dielectric layer to underlie a top electrode for improving the HV breakdown performance of the capacitor structure to be formed. In some arrangements, the thickness and compressive stress of the SiON layer 174 may be matched, balanced or otherwise optimized relative to and/or in view of the subsequent formation of a SiN bilayer having modulated RI characteristics so as to achieve a composite SiON/SiN layer with desirable thermomechanical properties and HV breakdown performance while avoiding or reducing the defectivity that would otherwise have been caused in forming the vias required for the next level metallization (e.g., MET5 metallization). Depending on implementation, various techniques and processes may be used for forming an SiON layer, e.g., thermal CVD or plasma-enhanced CVD, thermal atomic layer deposition (ALD) or plasma-enhanced ALD (PEALD), etc., using precursors and reactants such as silane (SiH₄), hexamethyldisilazane (HMDS), ammonia (NH₃), nitrous oxide (N₂O), oxygen (O₂), etc. Thereafter, a SiN bilayer 177 comprising a lower SiN layer 177B and an upper SiN layer 177A may be formed, resulting in a structure as shown in FIG. 2L. As previously noted, the upper SiN layer 177A and the lower SiN layer 177B may each have respective RI characteristics, e.g., the upper SiN layer 177A having a lower RI than the lower SiN layer 177B. As with the formation of the SiON layer 174, various techniques and processes may be used for forming the SiN layers 177A, 177B that may be suitably varied or modulated to achieve the desired RI properties. For example, silane gas flow in a deposition process using SiH₄ and NH₃ may be varied such that a higher silane flow rate (e.g., around 1000 sccm (standard cubic centimeters per minute)) may be used for forming a SiN film with higher RI values whereas a lower silane flow rate (e.g., around 600 sccm) may be used for forming a SiN film with lower RI values. Further, to match or optimize the overall compressive stress of the composite SiON/SiN structure, a high frequency radio frequency (HFRF) plasma at 800 W to 1200 W and having a pressure in the range of about 400 pascals (Pa) to 700 Pa may be used in some arrangements. Without limitation, the SiON layer 174 may have a compressive stress of about zero while the SiN bilayer 177 may have a compressive stress of about 100 MPa in an example implementation.

The SiN bilayer 177 may have a desired overall target thickness, e.g., around 500 nm to 800 nm, depending on the HV application, where the thickness of the upper SiN layer 177A may be less than the thickness of the lower SiN layer 177B by a fraction less than unity, e.g., about one-fifth (20%) or less. Because the upper SiN layer 177A (with lower RI) is expected to be lost or sacrificed due to subsequent via CMP erosion, a thicker upper SiN layer 177A may be initially deposited over the lower SiN layer 177B having a target thickness and required high RI characteristics. Vias 183 may be formed through the composite SiON/SiN layer 174/177, where there may be metal overburden 202 while filling the vias with suitable metal (e.g., W), as shown in FIG. 2M. A CMP/eCMP process may be used in removing the overburden 202 and for polishing the upper SiN layer 177A to a target thickness, resulting in a structure as shown in FIG. 2N.

In BEOL process flows that include the formation of a high RI SiN film directly underlying a top electrode of an HV isolation device, the via CMP process typically lands on the polished high RI SiN film. Because CMP (including eCMP) is generally an unclean process as noted previously, various types of particulate matter, metal whiskers, metal strings, granulated metallics, CMP slurry materials such as aggregates, agglomerates, and gels, debris such as microscopic flakes, flecks, shards etc. caused by routine wear and tear of the equipment components, and the like, which may be broadly referred to herein as “contaminants” or “surface defects”, may remain on the surface of the high RI SiN layer even after an aggressive post-CMP cleaning process. Where the vias are operable for providing top level connectivity, e.g., providing electrically conductive paths between a topmost MET level and a lower MET level, the contaminants on the SiN surface can remain encapsulated by subsequent conductive and/or dielectric layers, thereby increasing the risk of defectivity, which can negatively affect the HV breakdown performance of a device. The inventors of the present disclosure have discovered that the CMP-associated surface defect levels and the range of RI values of SiN films on which the CMP process lands are directly related, e.g., showing a positive correlation between the two variables. It is postulated herein that increased RI of a SiN film affects the Zeta (C) potential associated with the contaminants. The Zeta potential is a net electrokinetic potential resulting from the van der Waal attractive forces and electrical double-layer repulsive forces that may be established in a system containing particulate matter having charged surfaces, where the charged particulate matter may be in a suspension and/or on a material surface. With sufficient Zeta potential, which may be on the order of several millivolts in some examples, the particulate matter may form bonds with one another as well as with the material surface based on the phenomena such as flocculation and/or coagulation, which may render the particulate matter more resistant to a cleaning process. As high RI values of SiN films are directly related to the defectivity levels (e.g., in terms of surface defects, particulate counts, and/or defective parts per million (dppm), etc.), a BEOL process for forming composite SiON/SiN layers in HV isolation devices may be suitably characterized and/or qualified such that a SiN layer having a sufficiently low RI value may be process-engineered for a particular application requiring a level of defectivity that does not exceed a given threshold level. Because HV isolation performance requires a high RI SiN layer in some implementations, a combination of SiN materials having different RI characteristics may be optimized and provided as a bilayer structure according to the examples herein, where a low RI SiN material may form a thin upper layer for attenuating CMP-based defectivity levels (due to the expected reduction in Zeta potential interactions, which may also facilitate better surface potential control over the layer in the electrolytic solution) while a high RI SiN material may form a lower layer of sufficient thickness that affords acceptable HV isolation performance. For a given erosion amount, e.g., 100 nm to 150 nm of overburden, a CMP/eCMP process may be configured to have a suitable material removal rate endpoint for landing on the low RI SiN layer, thereby ameliorating the incidence of the surface defectivity levels according to some examples herein. An initial thickness of the low RI SiN layer may also be selected depending on how much material may be sacrificed in CMP, thickness of the low RI SiN layer relative to overall target thickness of the SiN bilayer, etc. In additional and/or alterative arrangements, the compressive stresses of the various components of a composite SiON/SiN layer may also be optimized while balancing the defectivity levels and HV isolation performance of an electronic device, e.g., device 100. It should be recognized upon reference hereto that the term “CMP” is inclusive of “eCMP” at least for purposes of some examples herein, depending on the context, unless otherwise noted.

As set forth previously, the composite SiON/SiN layer 174/177 may be operable as ILD4 in an example arrangement. Vias 183, e.g., tungsten, formed within the ILD4 are operable to connect MET4 structures 165 to upper MET5 structures 187 that may be formed at a subsequent stage. FIG. 2O depicts a fabrication stage where a top plate 105 has been formed as part of MET5 processing, which may include the formation of MET5 structures 187. In some optional examples, one or more isolation breaks or cutouts 180 may be formed in ILD4 after the formation of the top plate 105 to further improve lateral HV breakdown performance of the device 100 as set forth above. FIG. 2P depicts a fabrication stage where the optional cutouts 180 have been formed in ILD4 of the device 100. In some arrangements, the optional cutouts 180 formed in the layers 174 and 177A/177B may expose the underlying low-stress PE-TEOS layer 171. As noted previously, such cutouts 180 may be formed as described in U.S. Pat. No. 9,299,697, referenced hereinabove, which are expected to increase the robustness of the device 100 against dielectric breakdown between the top plate 105 and the guard ring 109 through the SiN bilayer components 177A/177B or along an interface between the SiON layer 174 and the SiN bilayer components 177A/177B. After forming the top plate 105, and optionally the cutouts 180, an HDP oxide layer 190 is formed over the top plate 105 and filling the cutouts 180, as shown in FIG. 2P. In FIG. 2Q, a TEOS layer 193 has been formed over the HDP oxide layer 190 and planarized, and a PO layer 196, e.g., SiON, has been formed over the TEOS layer 193. The PO layer 196 may have a compressive stress of about 160 MPa to about 180 MPa in some examples, without limitation. A wire bond opening, e.g., opening 199, may be formed over the top plate 105 by suitable patterning techniques, for connecting with a bond wire, thereby producing the device 100 as illustrated in FIG. 1A.

In some examples, high RI and low RI SiN layers underlying the top electrode 105 of the device 100 may be distinguished by ellipsometry where in-situ and/or offline RI measurements may be obtained for purposes of process characterization, qualification and/or statistical process quality control. In some examples, a physical cross-section of the device 100 may be analyzed and reverse engineered for differentiating between the high RI and low RI SiN layers.

The preceding description of the example 5 LM process sequence is not limited to any particular thicknesses of metal and/or dielectric layers. Further, a similar process sequence for depositing a combination SiN layer including two or more SiN sublayers with disparate RI values, respectively, may be provided in conjunction with any multilevel metal interconnect system having an arbitrary number of MET levels (e.g., 6 to 12 MET levels or more), where the top electrode of an isolation device is configured to be in direct contact with a low RI SiN sublayer.

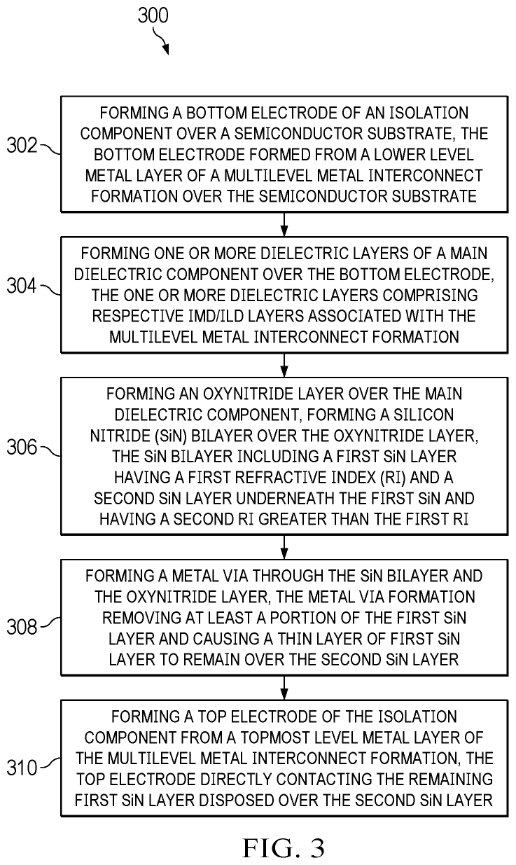

FIG. 3 is a flowchart of a method of fabricating an IC device including an HV isolation component according to some examples of the present disclosure. In one arrangement, an example method 300 may commence with forming a bottom electrode of an isolation component over a semiconductor substrate, where the bottom electrode may be formed from a lower level metal layer (e.g., MET2 level shown in FIGS. 2A-2Q) of a multilevel metal interconnect (MMI) formation over the semiconductor substrate, as set forth at block 302. At block 304, one or more dielectric layers of a main dielectric component may be formed over the bottom electrode, the one or more dielectric layers comprising respective IMD/ILD layers associated with the MMI formation. By way of illustration, portions of IMD2, ILD2, IMD3, ILD3, and IMD4 shown in FIGS. 2A-2Q may comprise a main dielectric component overlying the bottom electrode 104 in an example arrangement. At block 306, an oxynitride layer (e.g., comprising SiON) may be formed over the main dielectric component. Also, a SiN bilayer may be formed over the oxynitride layer (block 306), where the SiN bilayer includes a first SiN layer having a first RI and a second SiN layer underneath the first SiN, the second SiN layer having a second RI greater than the first RI. At block 308, metal vias may be formed through the SiN bilayer and the oxynitride layer, where the metal via formation may involve a CMP process for removing metal overburden as well as at least a portion of the first SiN layer, thereby causing a thin layer of first SiN material to remain over the second SiN layer. As set forth previously, the target thicknesses and RI values of the two SiN layers of a bilayer may be optimized relative to each other so as to achieve an acceptable balance between the desired HV breakdown performance, reduction in defectivity and/or compressive stress performance of the films, which may be based on the process characterization of a BEOL flow used in IC fabrication. At block 310, a top electrode of the isolation component may be formed from a topmost level metal layer of the MMI formation, the top electrode directly contacting the remaining first SiN layer disposed over the second SiN layer for achieving appropriate capacitive coupling with the bottom electrode required for HV breakdown performance.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. An integrated circuit (IC), comprising:
a semiconductor substrate;
a metal bottom plate over the semiconductor substrate;
a metal top plate over the metal bottom plate; and
a dielectric structure disposed between the top and bottom plates, the dielectric structure including a silicon nitride (SiN) bilayer underlying the top plate, the SiN bilayer including a first SiN layer directly contacting the top plate and having a first refractive index (RI), and a second SiN layer underneath and directly contacting the first SiN and having a second RI greater than the first RI.

2. The IC as recited in claim 1, wherein the first SiN layer has an RI of about 2.0 to 2.15.

3. The IC as recited in claim 1, wherein the second SiN layer has an RI of about 2.2 to 2.4.

4. The IC as recited in claim 1, wherein the first SiN layer has a thickness less than about 20% of a total thickness of the SiN bilayer.

5. The IC as recited in claim 1, wherein the first SiN layer has a thickness of about 50 nanometers (nm) to 100 nm.

6. The IC as recited in claim 1, wherein the second SiN layer has a thickness of about 500 nm to 700 nm.

7. The IC as recited in claim 1, wherein the SiN bilayer extends beyond the top plate.

8. The IC as recited in claim 7, wherein the SiN bilayer includes an isolation break region in a portion extending beyond the top plate.

9. The IC as recited in claim 1, wherein the SiN bilayer is disposed over an oxynitride layer overlying a main dielectric component of the dielectric structure, the main dielectric component having a thickness of at least 2 microns (μm).

10. The IC as recited in claim 1, wherein the top plate is formed from a topmost metal layer of a multilevel metal interconnect formation over the semiconductor substrate.

11. The IC as recited in claim 1, wherein the bottom plate is formed from an intermediate metal layer of a multilevel metal interconnect formation over the semiconductor substrate.

12. A method of fabricating an integrated circuit (IC), comprising:
forming a bottom electrode of an isolation component over a semiconductor substrate; and
forming a dielectric structure between the bottom electrode and a top electrode of the isolation component, the dielectric structure including a silicon nitride (SIN) bilayer underlying the top electrode, the SiN bilayer including a first SiN layer directly contacting the top electrode and having a first refractive index (RI), and a second SiN layer underneath and directly contacting the first SiN and having a second RI greater than the first RI.

13. The method as recited in claim 12, wherein the first RI is in a range from about 2.0 to about 2.15.

14. The method as recited in claim 12, wherein the second RI is in a range from about 2.2 to about 2.4.

15. The method as recited in claim 12, wherein the first SiN layer has a thickness less than about 20% of a total thickness of the SiN bilayer.

16. The method as recited in claim 12, further comprising forming an isolation break region in a portion of the SiN bilayer extending beyond the top electrode.

17. The method as recited in claim 12, wherein the SiN bilayer is formed over an oxynitride layer overlying a main dielectric component of the dielectric structure, the main dielectric component overlying the bottom electrode and having a thickness of at least 2 microns (μm).

18. The method recited in claim 12, wherein the top electrode is formed from a topmost metal layer of a multilevel metal interconnect formed over the semiconductor substrate.

19. The method as recited in claim 12, wherein the bottom electrode is formed from an intermediate metal layer of a multilevel metal interconnect formed over the semiconductor substrate.
